(19) United States
(12) Patent Application Publication
(10) Pub. No.: US 2005/0110137 A1
(43) Pub. Date: May 26, 2005

(54) Plastic dual-in-line packaging (PDIP) having enhanced heat dissipation

(75) Inventor: Anthony L. Coyle, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/723,036

(22) Filed: Nov. 25, 2003

(51) Int. Cl. H01L 23/48

(52) U.S. Cl. 257/735

(57) ABSTRACT

According to one embodiment, an electronic device comprising a plastic dual-in-line packaging (PDIP) package structure is provided. The PDIP package structure includes a mold structure, a die disposed within the mold structure, and a die attach pad coupled to the die. The die attach pad has a first surface exposed from the mold structure.

### TECHNICAL FIELD OF THE INVENTION

This invention relates in general to die packaging, and, more particularly, to a plastic dual-in-line packaging (PDIP) having enhanced heat dissipation.

### BACKGROUND OF THE INVENTION

Plastic dual-in-line packaging (PDIP) is a typical die or chip package using pin-through-hole (PTH) technology. PDIP packages include various numbers of pins, or leads. For example, common PDIP packages include 28-pin PDIPs and 40-pin PDIPs. PDIP packages are widely used for low cost and hand-inserting applications. In addition, PDIP packages are relatively large, and thus are often used where small size is not a high priority. PDIP packages broad application includes consumer products, automotive devices, logic, memory ICs, microcontrollers, logic and power ICs, video controllers commercial electronics and telecommunications.

As dies (or chips) have become smaller and more dense, the heat generated during the operation of such dies has increased accordingly. As a result, the amount of power that can be applied to a PDIP die is often limited by temperature concerns caused by the heat generated by the die.

### SUMMARY OF THE INVENTION

In accordance with the present invention, a plastic dual-in-line packaging (PDIP) having enhanced heat dissipation. According to one embodiment, an electronic device comprising a plastic dual-in-line packaging (PDIP) package structure is provided. The PDIP package structure includes a mold structure, a die disposed within the mold structure, and a die attach pad coupled to the die. The die attach pad has a first surface exposed from the mold structure.

According to another embodiment, an electronic device including a plastic dual-in-line packaging (PDIP) package structure and a conductive structure adjacent the PDIP package structure is provided. The PDIP package structure includes a mold structure having a first surface, a die disposed within the mold structure, and a die attach pad coupled to the die. The die attach pad has a first surface exposed from and substantially flush with the first surface of the mold structure. The PDIP package structure also includes a plurality of conductive leads and a conductive portion disposed at least substantially within the mold structure. The conductive portion is coupled to the die attach pad and a portion of the plurality of leads such that heat is removed from the die via the die attach pad, the conductive portion and the portion of leads. The conductive structure adjacent the PDIP package structure is in thermal communication with the exposed first surface of the die attach pad such that heat is removed from the die via the die attach pad and the conductive structure.

According to yet another embodiment, a method of forming an electronic device is provided. The method in includes forming a plastic dual-in-line packaging (PDIP) package structure by providing a die attach pad, attaching a die to the die attach pad, and forming a mold structure at least substantially around the die such that the die attach pad has a first surface exposed from the mold structure.

Various embodiments of the present invention may benefit from numerous advantages. It should be noted that one or more embodiments may benefit from some, none, or all of the advantages discussed below.

One advantage is that in one embodiment, a surface or portion of the die attach pad in a PDIP package is exposed from the generally insulative mold compound of the PDIP package, thus allowing increased heat transfer away from the die through the die attach pad. The exposed portion of the die attach pad may be exposed to the surrounding air, which allows for heat dissipation to the surrounding environment. Alternatively, the exposed portion of the die attach pad may be thermally coupled to a conductive portion of a motherboard or a heat sink, thus providing a conductive path for heat transfer or dissipation away from the PDIP die.

Another advantage is that a conductive region may be provided to couple a number of the leads of the PDIP package to the die attach pad, thus providing another conductive path for heat transfer or dissipation away from the PDIP die. This heat dissipation is particularly important for dies or chips that generate relatively large amounts of heat, such as small or dense chips.

Other advantages will be readily apparent to one having ordinary skill in the art from the following figures, descriptions, and claims.

### BRIEF DESCRIPTION OF THE DRAWINGS

For a more complete understanding of the present invention and for further features and advantages, reference is now made to the following description, taken in conjunction with the accompanying drawings, in which:

FIG. 1 illustrates a top view of a plastic dual-in-line packaging (PDIP) in accordance with one embodiment of the present invention;

FIG. 2 illustrates a cross-sectional view of the PDIP package taken along line A-A in FIG. 1 in accordance with one embodiment of the present invention;

FIG. 3 illustrates a cross-sectional view of the PDIP package taken along line A-A in FIG. 1 in accordance with another embodiment of the present invention;

FIG. 4 illustrates a top view of another PDIP package in accordance with another embodiment of the present invention; and

FIG. 5 illustrates a cross-sectional view of the PDIP package taken along line B-B in FIG. 1.

### DETAILED DESCRIPTION OF THE DRAWINGS

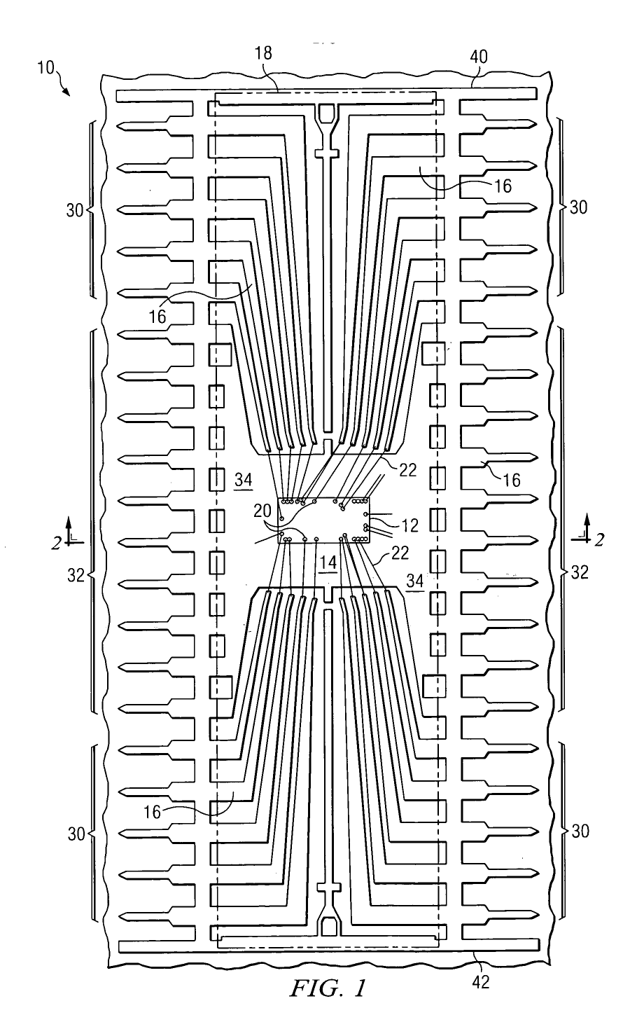

Example embodiments of the present invention and their advantages are best understood by referring now to FIGS. 1 through 5 of the drawings, in which like numerals refer to like parts.

FIG. 1 illustrates a top view of a plastic dual-in-line packaging (PDIP) package 10 in accordance with one embodiment of the present invention. PDIP package 10 includes a die 12 coupled to a die attach pad 14, a plurality of conductive leads 16, and a mold structure 18.

Die 12, which may be called a chip or microchip, may be any type of semiconductor device, such as an ASIC, a CPLD, a Flash device, an FPGA, a microcontroller, or an SOC, for example. Die 12 includes a number of contact points 20 to which conductive wires 22 are attached to create connections with various leads 16. Conductive wires 22 are formed from one or more suitable conductive materials, such as copper, gold or aluminum, for example. Conductive wires 22 may be relatively thin wires. For example, in one embodiment, wires 22 have a diameter of approximately 1 mil.

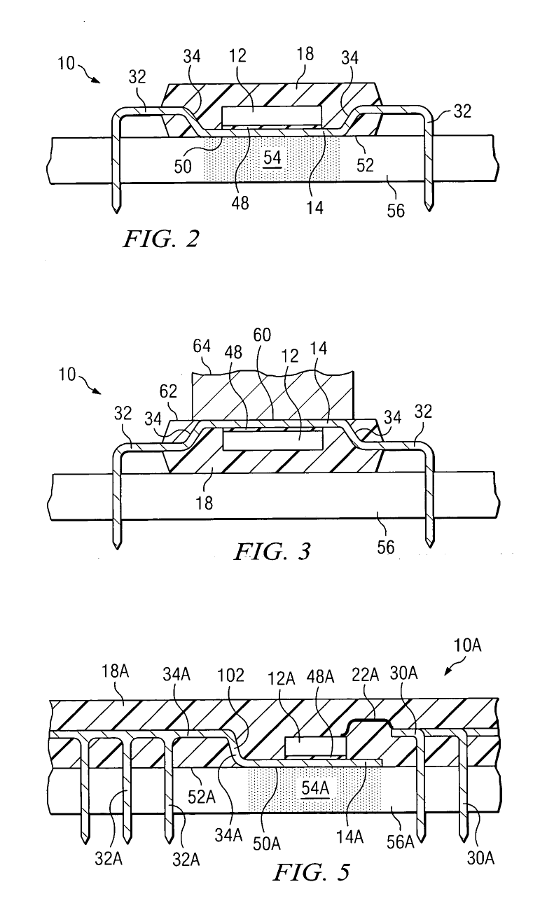

Die attach pad 14 generally attaches die 12 to mold structure 18. Die attach pad 14 may be formed from one or more conductive materials, such as copper, gold or aluminum, for example. Die 12 is coupled to die attach pad 14 by a die attach adhesive, as discussed below with reference to FIG. 2. It should be understood that in other embodiments, two or more dies 12 may attached to the die attach pad 14 of a PDIP package.

A row of conductive leads (or pins) 16 is provided on each side of PDIP package 10. In the embodiment shown in FIG. 1, PDIP package 10 is a 40-pin PDIP and thus includes forty leads 16. However, in other embodiments, PDIP may include any suitable number of leads 16. For example, PDIP package 10 is a 28-pin PDIP. Leads 16 are formed from one or more conductive materials, such as copper, gold or aluminum, for example. A portion of the leads 16, which may be referred to as active leads 30, are connected to die 12 by one or more conductive wires 22, as discussed above.

Another portion of the leads 16, which may be referred to as inactive leads 32, are connected to die attach pad 14 by a conductive region or portion 34 formed on each side of die attach pad 14. Thus inactive leads 32 are effectively ground leads. Conductive regions 34 are formed from any one or more suitable conductive materials, such as copper, gold or aluminum, for example. Conductive regions 34 may be integral with inactive leads 32 and/or die attach pad 14. For example, conductive regions 34 may be formed as an extension of die attach pad 14. As another example, die attach pad 14, inactive leads 32, and conductive regions 34 may be formed as an integral structure.

Mold structure 18, represented by the dotted line in FIG. 1, is formed partially or completely around each of die 12, die attach pad 14, wires 22, active leads 30, inactive leads 32, and conductive regions 34. Mold structure 18 disposed on the top side of package 10 is shown transparently in FIG. 1 in order to provide a better view of the various components within package 10. Mold structure 18 may be formed from one or more generally non-conductive materials, such as one or more plastics.

Together, the conductive die attach pad 14, conductive regions 34, and conductive inactive leads 32 provide a conductive path for heat generated by die 12 to be transferred or dissipated away from die 12. As a result, more power may be applied during the operation of die 12, which is desirable in many applications. This heat dissipation has become increasingly importance as the density of chips 12 has increased over time.

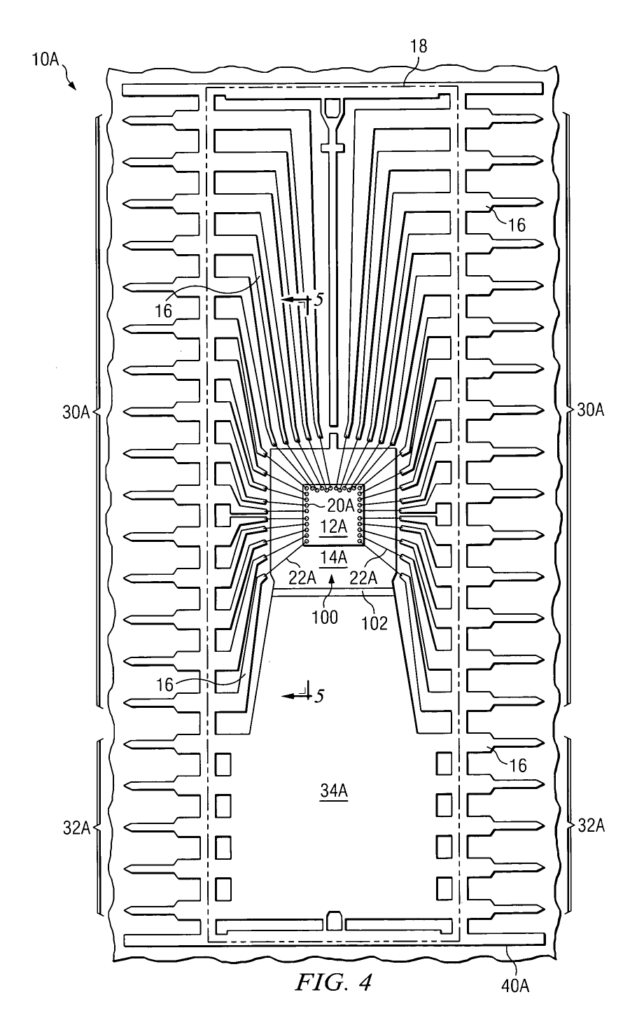

In the embodiment shown in FIG. 1, active leads 30 include the leads 16 near a first end 40 and a second end 42 of PDIP package 10, and inactive leads 32 include the leads 16 in between the active leads 30 near the first and second ends 40 and 42 of package 10. In alternative embodiments, active leads 30 may include any suitable number and configuration of leads 16. For example, in one embodiment discussed below and shown in FIG. 4, the leads near a first end of the PDIP package are configured as active leads, while the leads near a second end of the PDIP package are configured as inactive leads used for dissipating heat from the die.

FIG. 2 illustrates a cross-sectional view of PDIP package 10 taken along line A-A in FIG. 1 in accordance with one embodiment of the present invention. Die 12 is coupled to die attach pad 14 by a die attach adhesive 48, such as an epoxy. As discussed above, mold structure 18 is formed partially or completely around die 12, die attach pad 14, wires 22, active leads 30, inactive leads 32, and conductive regions 34. However, PDIP package 10 is configured such that a first, or bottom, surface 50 of die attach pad 14 is exposed from the bottom portion of mold structure 18. In this embodiment, surface 50 of die attach pad 14 is exposed from and substantially flush with a first, or bottom, surface 52 of mold structure 18.

Conductive regions 34 are configured such that die attach pad 14 and die 12 may be formed near the bottom portion of package 10. In particular, conductive regions 34 may be angled relative to die attach pad 14 and/or may include one or more bends in order to connect inactive leads 32 with die attach pad 14.

Because surface 50 of die attach pad 14 is exposed from the generally non-conductive mold structure 18, additional heat may be transferred or dissipated away from die 12 via die attach pad 14. In some embodiments, surface 50 of die attach pad 14 is exposed to the surrounding air, which allows for heat dissipation via conduction, convection and/or radiation to the surrounding environment. In other embodiments, such as shown in FIGS. 2 and 3, surface 50 of die attach pad 14 is contacted by another conductive structure in order to transfer heat away from die 12.

In the embodiment shown in FIG. 2, surface 50 of die attach pad 14 is disposed in contact with a conductive portion 54 of a motherboard 56. Thus, heat generated by die 12 is transferred through die attach pad 14 and into conductive portion 54 of motherboard 56, in addition to the heat transfer discussed above with regard to FIG. 1 (heat transfer from die 12 to die attach pad 14 to conductive regions 34 and to inactive leads 32).

FIG. 3 illustrates a cross-sectional view of PDIP package 10 taken along line A-A of FIG. 1 in accordance with another embodiment of the present invention. Like the embodiment shown in FIG. 2, mold structure 18 is formed partially or completely around die 12, die attach pad 14, wires 22, active leads 30, inactive leads 32, and conductive regions 34. However, in the embodiment shown in FIG. 3, PDIP package 10 is configured such that a first, or top, surface 60 of die attach pad 14 is exposed from the top portion of mold structure 18. In particular, surface 60 of die attach pad 14 is exposed from and substantially flush with a first, or top, surface 62 of mold structure 18.

Conductive regions 34 are configured such that die attach pad 14 and die 12 may be formed near the top portion of package 10. Again, conductive regions 34 may be angled relative to die attach pad 14 and/or may include one or more bends in order to connect inactive leads 32 with die attach pad 14.

As discussed above with regard to surface 50 of the embodiment shown in FIG. 2, because surface 60 of die attach pad 14 is exposed from the generally non-conductive mold structure 18, additional heat may be transferred or dissipated away from die 12 via die attach pad 14. In some embodiments, surface 60 of die attach pad 14 is exposed to the surrounding air, which allows for heat dissipation via conduction, convection and/or radiation to the surrounding environment. In other embodiments, such as shown in FIGS. 2 and 3, surface 60 of die attach pad 14 is contacted by another conductive structure in order to transfer heat away from die 12.

In the embodiment shown in FIG. 3, a heat sink 64 is disposed in contact with the surface 60 of die attach pad 14. Thus, heat generated by die 12 is transferred through die attach pad 14 and into heat sink 64, in addition to the heat transfer discussed above with regard to FIG. 1 (heat transfer from die 12 to die attach pad 14 to conductive regions 34 and to inactive leads 32).

FIG. 4 illustrates a top view of another PDIP package 10A in accordance with another embodiment of the present invention. PDIP package 10A includes a die 12A coupled to a die attach pad 14A, a plurality of conductive leads 16A, and a mold structure 18A.

Die 12A includes a number of contact points 20A to which conductive wires 22A are attached to create connections with various leads 16A. Die attach pad 14A generally attaches die 12A to mold structure 18A. Die 12A is coupled to die attach pad 14A by a die attach adhesive, as discussed below with reference to FIG. 5.

A row of conductive leads (or pins) 16A is provided on each side of PDIP package 10A. A portion of the leads 16A, which may be referred to as active leads 30A, are connected to die 12A by one or more conductive wires 22A, as discussed above. Another portion of the leads 16A, which may be referred to as inactive leads 32A, are connected to die attach pad 14A by a conductive region or portion 34A coupled to, or integral with, a first side 100 of die attach pad 14A. Thus inactive leads 32A are effectively ground leads. In the embodiment shown in FIG. 4, inactive leads 32A include the leads 16A near a first end 40A of PDIP package 10A, and active leads 30A include the remaining leads 16A provided by package 10.

Conductive region 34A is formed from any one or more suitable conductive materials, such as copper, gold or aluminum, for example. Conductive region 34A may be integral with inactive leads 32A and/or die attach pad 14A. For example, conductive region 34A may be formed as an extension of die attach pad 14A. As another example, die attach pad 14A, inactive leads 32A, and conductive region 34A may be formed as an integral structure. In some embodiments, such as the embodiment shown in FIG. 4, conductive region 34A includes a transition region 102 which provides a transition from die attach pad 14A to the remainder of conductive region 34A.

Mold structure 18A, represented by the dotted line in FIG. 4, is formed partially or completely around each of die 12A, die attach pad 14A, wires 22A, active leads 30A, inactive leads 32A, and conductive region 34A. Mold structure 18A disposed on the top side of package 10A is shown transparently in FIG. 4 in order to provide a better view of the various components within package 10A.

Together, the conductive die attach pad 14A, conductive region 34A, and conductive inactive lead 32 provide a conductive path for heat generated by die 12A to be transferred or dissipated away from die 12A, which may be advantageous as described above with reference to FIG. 1.

FIG. 5 illustrates a cross-sectional view of the PDIP package taken along line B-B of FIG. 1. Die 12A is coupled to die attach pad 14A by a die attach adhesive 48A, such as an epoxy. As discussed above, mold structure 18A is formed partially or completely around die 12A, die attach pad 14A, wires 22A, active leads 30A, inactive leads 32A, and conductive regions 34A. However, PDIP package 10A is configured such that a first, or bottom, surface 50A of die attach pad 14A is exposed from the bottom portion of mold structure 18A. In this embodiment, surface 50A of die attach pad 14A is exposed from and substantially flush with a first, or bottom, surface 52A of mold structure 18A.

Conductive region 34A, including transition region 100, is configured such that die attach pad 14A and die 12A may be formed near the bottom portion of package 10A. In particular, transition region 100 is angled relative to die attach pad 14A in order to connect inactive leads 32A with die attach pad 14A. Conductive region 34A may include other suitable bends or angled portions in order to connect inactive leads 32A with die attach pad 14A.

Because surface 50A of die attach pad 14 is exposed from the generally non-conductive mold structure 18A, additional heat may be transferred or dissipated away from die 12A via die attach pad 14A, as discussed above with regard to FIG. 2. In some embodiments, surface 50A of die attach pad 14A is exposed to the surrounding air, which allows for heat dissipation via conduction, convection and/or radiation to the surrounding environment. In other embodiments, surface 50A of die attach pad 14A is contacted by another conductive structure in order to transfer heat away from die 12A.

In the embodiment shown in FIG. 5, surface 50A of die attach pad 14A is disposed in contact with a conductive portion 54A of a motherboard 56A. Thus, heat generated by die 12A is transferred through die attach pad 14A and into conductive portion 54A of motherboard 56A, in addition to the heat transfer discussed above with regard to FIG. 4 (heat transfer from die 12A to die attach pad 14A to conductive regions 34A and to inactive leads 32A).

Although embodiments of the invention and its advantages have been described in detail, a person skilled in the art could make various alterations, additions, and omissions without departing from the spirit and scope of the present invention as defined by the appended claims.

1. An electronic device comprising a plastic dual-in-line packaging (PDIP) package structure, the PDIP package structure including:
a mold structure;
a die disposed within the mold structure; and
a die attach pad coupled to the die, the die attach pad having a first surface exposed from the mold structure.

2. The electronic device of claim 1, further comprising a motherboard, wherein the exposed first surface of the die attach is thermally coupled to the motherboard.

3. The electronic device of claim 2, wherein the exposed first surface of the die attach is in direct contact with the motherboard.

4. The electronic device of claim 1, wherein the mold structure has a first surface, and wherein the first surface of the die attach pad is exposed from and substantially flush with the first surface of the mold structure.

5. The electronic device of claim 1, further comprising a heat sink disposed in thermal communication with the exposed first surface of the die attach pad.

6. The electronic device of claim 1, further comprising a motherboard, wherein the mold structure has a first side generally facing the motherboard and a second side opposite the first side, and wherein the first surface of the die attach is exposed from the second side of the mold structure.

7. The electronic device of claim 1, wherein the PDIP package structure further includes a plurality of leads, a portion of the plurality of leads extending into contact with the die attach pad such that portion of leads are ground leads that remove heat from the die attach pad.

8. The electronic device of claim 1, wherein the PDIP package structure further includes:
a plurality of leads;
and a conductive portion coupled to the die attach pad and a portion of the plurality of leads such that heat is removed from the die via the die attach pad, the conductive portion and the portion of leads.

9. The electronic device of claim 1, wherein the PDIP package structure further includes:
a plurality of active leads, each coupled to the die by a conductive wire;
a plurality of inactive leads; and
a conductive portion coupled to the die attach pad and to each of the plurality of inactive leads such that heat is removed from the die via the die attach pad, the conductive portion and the plurality of inactive leads.

10. The electronic device of claim 9, wherein the plurality of active leads includes a first portion of active leads located generally near a first end of the PDIP package structure and a second portion of active leads located generally near a second end of the PDIP package structure, the second end of the PDIP package structure located generally opposite the first end of the PDIP package structure; and
wherein the plurality of inactive leads are located generally between the first and second portions of active leads.

11. The electronic device of claim 9, wherein the plurality of active leads are located generally near a first end of the PDIP package, and the plurality of inactive leads are located generally near a second end of the PDIP package, the second end of the PDIP package structure located generally opposite the first end of the PDIP package structure.

12. An electronic device comprising:
a plastic dual-in-line packaging (PDIP) package structure, the PDIP package structure including:
a mold structure having a first surface;
a die disposed within the mold structure;
a die attach pad coupled to the die, the die attach pad having a first surface exposed from and substantially flush with the first surface of the mold structure;
a plurality of conductive leads; and
a conductive portion disposed at least substantially within the mold structure, the conductive portion coupled to the die attach pad and a portion of the plurality of leads such that heat is removed from the die via the die attach pad, the conductive portion and the portion of leads; and
a conductive structure adjacent the PDIP package structure and in thermal communication with the exposed first surface of the die attach pad such that heat is removed from the die via the die attach pad and the conductive structure.

13. The electronic device of claim 12, further comprising a motherboard adjacent the PDIP package structure;
wherein the first surface of the mold structure faces generally away from the motherboard; and
wherein the conductive structure is a heat sink.

14. The electronic device of claim 12, further comprising a motherboard adjacent the exposed first surface of the die attach pad; and
wherein the conductive structure forms a portion of the motherboard.

15. A method of forming an electronic device, comprising forming a plastic dual-in-line packaging (PDIP) package structure by:
providing a die attach pad;
attaching a die to the die attach pad; and
forming a mold structure at least substantially around the die such that the die attach pad has a first surface exposed from the mold structure.

16. The method of claim 15, further comprising providing a motherboard and configuring the PDIP package structure such that the exposed first surface of the die attach is thermally coupled to the motherboard.

17. The method of claim 15, further comprising configuring the PDIP package structure such that the first surface of the die attach pad is exposed from and substantially flush with a first surface of the mold structure.

18. The method of claim 15, further comprising configuring a heat sink in thermal communication with the exposed first surface of the die attach pad such that the heat sink removes heat from the die attach pad.

19. The method of claim 15, further comprising providing a motherboard; and configuring the mold structure such that a first side of the mold structure generally faces the motherboard and the first surface of the die attach is exposed from the second side of the mold structure opposite the first side of the mold structure.

20. The method of claim 15, wherein forming the PDIP package structure further includes configuring a plurality of leads such that each lead extends into contact with the die attach pad such that portion of leads are ground leads that remove heat from the die attach pad.

21. The method of claim 15, wherein forming the PDIP package structure further includes:
providing a plurality of leads; and
forming a conductive portion coupled to the die attach pad and a portion of the plurality of leads such that heat is removed from the die via the die attach pad, the conductive portion and the portion of leads.
